(19) United States
(12) Patent Application Publication
(10) Pub. No.: US 2025/0374502 A1
(43) Pub. Date: Dec. 4, 2025

(54) SEMICONDUCTOR STRUCTURE WITH BACKSIDE CONTACTS

(71) Applicant: Taiwan Semiconductor Manufacturing Company, Ltd., Hsin-Chu (TW)

(72) Inventors: Yung-Ting Chang, New Taipei City (TW); Jui-Lin Chen, Taipei City (TW); Chih-Ching Wang, Kinmen County (TW)

(21) Appl. No.: 19/287,298

(22) Filed: Jul. 31, 2025

Related U.S. Application Data
(63) Continuation of application No. 18/674,071, filed on May 24, 2024.
(60) Provisional application No. 63/612,143, filed on Dec. 19, 2023.

(51) Int. Cl. H10B 10/00; H10D 30/67; H10D 62/10; H10D 62/13; H10D 64/01; H10D 84/83

(52) U.S. Cl. CPC H10B 10/12; H10D 62/118; H10D 62/151; H10D 64/018; H10D 84/83; H10D 30/6735; H10D 30/6757

(57) ABSTRACT

A semiconductor structure includes an epitaxial feature disposed in an active region, a frontside contact disposed directly above and in electrical coupling with the epitaxial feature, a metal gate stack, an inner spacer interposing the metal gate stack and the epitaxial feature, and a backside contact in physical contact with a bottom portion of the metal gate stack and in physical contact with a bottom portion of the frontside contact.

This is a continuation application of U.S. patent application Ser. No. 18/674,071, filed May 24, 2024, which claims benefit of U.S. Provisional Patent Application No. 63/612,143, filed Dec. 19, 2023, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

In deep sub-micron integrated circuit technology, static random-access memory (SRAM) device has become a popular storage unit of high-speed communication, image processing, and system-on-chip (SOC) products. As silicon technology continues to scale from one generation to the next, conventional SRAM devices and/or the fabrication thereof may encounter limitations. For example, aggressive scaling down of IC dimensions has resulted in densely spaced source/drain features and gate structures, and densely spaced source/drain contacts and gate vias formed thereover. In some SRAM devices, multilayer interconnect structure providing metal lines for interconnecting power lines and signal lines in and between memory cells of the SRAM devices are formed over source/drain contacts and gate vias of the transistors of the memory cells. With ever-decreasing device sizes and densely spaced transistors, interconnect features (e.g., contacts, vias, and metal lines) are formed to have reduced dimensions, which may lead to increased parasitic resistance, increased parasitic capacitance, high process risk, and/or poor connection, which may degrade the speed of the memory devices. All those issues present performance, yield, and cost challenges. Therefore, while existing SRAM devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a circuit schematic of a static random-access memory (SRAM) cell, in accordance with some embodiments of the present disclosure.

FIG. 2 illustrates a cross-sectional view of various layers of a memory device, in accordance with some embodiments of the present disclosure.

FIG. 3 illustrates a fragmentary layout of an exemplary memory device, in accordance with some embodiments of the present disclosure.

FIGS. 4A, 4B, 4C, and 4D illustrate fragmentary cross-sectional views of the exemplary memory device along lines A-A, B-B, C-C, and D-D of FIG. 3, respectively, in accordance with some embodiments of the present disclosure.

FIG. 5 illustrates a flowchart of a method for forming a semiconductor device, in accordance with some embodiments of the present disclosure.

FIGS. 6, 7, 8, 9, 10, 11, 12, 13, and 14 illustrate fragmentary cross-sectional views of an exemplary workpiece during a fabrication process according to the method of FIG. 5 along lines C-C and D-D of FIG. 3, in accordance with some embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

Static random-access memory (SRAM) is an electronic data storage device implemented on a semiconductor-based integrated circuit and generally has much faster access times than other types of data storage technologies. SRAM is popular in high-speed communication, image processing and system-on-chip (SOC) applications. A bit can be read from or written into an SRAM cell within a few nanoseconds. An SRAM cell include transistors with metal interconnect structures above the transistors. The metal interconnect structures include metal lines for interconnecting transistor gates and source/drain regions, such as signal lines for routing bit line and word line signals to the cell components, as well as power rails (such as metal lines for power voltage and electrical ground) for providing power to the cell components. Some contacts and respective contact vias electrically connect the cell components to the signal lines and the power rails. For example, some of the source/drain regions in an SRAM cell are coupled to a power voltage VDD (also referred to as VCC) and/or an electrical ground VSS through source/drain contacts, source/drain contact vias, and respective metal lines in the power rails. Some other contacts, also known as butted contacts, each abut two conductive regions and can reduce the number of contacts needed. For example, a butted contact in an SRAM cell may include a bottom surface landing on a gate electrode, and another bottom surface landing on an active region such as a source/drain region or the respective overlying silicide feature. Source/drain region(s) may refer to a source or a drain, individually or collectively dependent upon the context.

Conventionally, SRAM devices are built in a stacked-up fashion, having transistors at the lowest level and interconnect structures (contacts, vias, and metal lines) on top of the transistors to provide connectivity to the transistors. For example, interconnect structures may include a butted contact that electrically connects a common source/drain region of a first pull-down transistor and a first pull-up transistor to a common gate of a second pull-down transistor and a second pull-up transistor. If the butted contact is incorporated in the frontside interconnect structure, it will take up already limited space above the transistors. On the other hand, the butted contact may be incorporated in the backside interconnect structure, without taking precious layout resource above the transistors. As a result, the density of the conductive contacts on the front-side of the device layer is reduced, which may reduce shorting and parasitic capacitance between adjacent conductive contacts on the front-side of the device layer, thereby improving the performance and the long-term reliability of the semiconductor die. However, if forming a backside butted contact in an SRAM device involves steps like creating a backside opening over a source/drain feature and recessing the source/drain feature through this opening before depositing a backside butted contact, this process flow would reduce the volume of the source/drain feature. A reduced volume in the source/drain feature typically leads to strain loss in the source/drain region, which generally affects the performance of p-type transistors. Therefore, although existing approaches in semiconductor fabrication have been generally adequate for their intended purposes, they have not been entirely satisfactory in all respects in the context of memory devices, such as SRAM devices.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to GAA transistors or other particular type of transistors (e.g., FinFET transistors), except as specifically claimed.

The present disclosure provides various embodiments of a semiconductor device. Particularly, some embodiments of the present disclosure provide a semiconductor device with a backside butted contact. The semiconductor device includes a stack of nanostructures (e.g., nanosheets or nanowires), a gate stack over the stack of nanostructures, a source/drain feature contacting the stack of nanostructures, and a source/drain contact landing on the frontside of the source/drain feature. The stack of nanostructures may be at an end portion of an active region. The backside butted contact extends from a backside of the semiconductor device to directly contact a bottom portion of the gate stack and a bottom portion of the source/drain contact. Thus, the backside butted contact electrically connects the gate stack and the source/drain feature through the source/drain contact without a direct contact with the source/drain feature. In a top view of the semiconductor device, the backside butted contact does not overlap with the source/drain feature. As a result, the source/drain feature remains unexposed and is not subjected to etching loss during the formation of the backside butted contact. Because the butted contact is formed on the backside of the semiconductor device, frontside via density of the semiconductor device may be reduced, providing increased space for frontside conductive features, such as metal lines and vias. The semiconductor device may include SRAM cells. It is understood, however, that the application should not be limited to SRAM devices or other particular type of devices (e.g., other memory devices), except as specifically claimed.

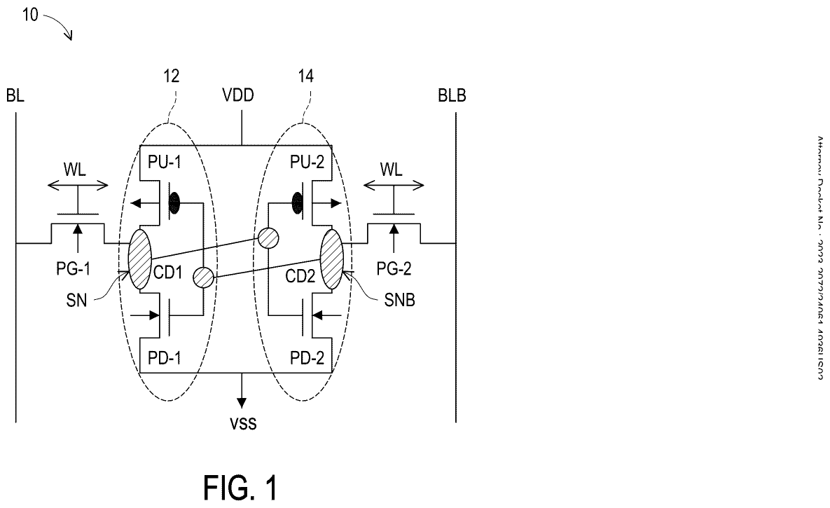

Reference now is made to FIG. 1. FIG. 1 is a circuit diagram of an exemplary SRAM cell 10. In the illustrated embodiment, the SRAM cell 10 is a single-port (SP) six-transistor (6T) SRAM cell. In various embodiments, the SRAM cell 10 may be other types of memory cells, such as dual-port memory cell or a memory cell having more than six transistors. FIG. 1 has been simplified for the sake of clarity to better understand the inventive concepts of the present disclosure. Additional features can be added in the SRAM cell 10, and some of the features described below can be replaced, modified, or eliminated in other embodiments of the SRAM cell 10.

The exemplary SRAM cell 10 is a single port SRAM cell that includes six transistors: a pass-gate transistor PG-1, a pass-gate transistor PG-2, a pull-up transistor PU-1, a pull-up transistor PU-2, a pull-down transistor PD-1, and a pull-down transistor PD-2. In operation, the pass-gate transistor PG-1 and the pass-gate transistor PG-2 provide access to a storage portion of the SRAM cell 10, which includes a cross-coupled pair of inverters, an inverter 12 and an inverter 14. The inverter 12 includes the pull-up transistor PU-1 and the pull-down transistor PD-1, and the inverter 14 includes the pull-up transistor PU-2 and the pull-down transistor PD-2. In some implementations, the pull-up transistors PU-1, PU-2 are configured as p-type transistors, such as p-type GAA transistors, and the pull-down transistors PD-1, PD-2 are configured as n-type transistors, such as n-type GAA transistors.

A gate of the pull-up transistor PU-1 interposes a source (electrically coupled with a power supply voltage (VDD)) and a first common drain (CD1), and a gate of pull-down transistor PD-1 interposes a source (electrically coupled with a power supply voltage (VSS), which may be an electric ground) and the first common drain. A gate of pull-up transistor PU-2 interposes a source (electrically coupled with the power supply voltage (VDD)) and a second common drain (CD2), and a gate of pull-down transistor PD-2 interposes a source (electrically coupled with the power supply voltage (VSS)) and the second common drain. In some implementations, the first common drain (CD1) is a storage node (SN) that stores data in true form, and the second common drain (CD2) is a storage node (SNB) that stores data in complementary form. The gate of the pull-up transistor PU-1 and the gate of the pull-down transistor PD-1 are coupled with the second common drain (CD2), and the gate of the pull-up transistor PU-2 and the gate of the pull-down transistor PD-2 are coupled with the first common drain (CD1). A gate of the pass-gate transistor PG-1 interposes a source (electrically coupled with a bit line BL) and a drain, which is electrically coupled with the first common drain (CD1). A gate of the pass-gate transistor PG-2 interposes a source (electrically coupled with a complementary bit line BLB) and a drain, which is electrically coupled with the second common drain (CD2). The gates of the pass-gate transistors PG-1, PG-2 are electrically coupled with a word line WL. In some implementations, the pass-gate transistors PG-1, PG-2 provide access to the storage nodes SN, SNB during read operations and/or write operations. For example, the pass-gate transistors PG-1, PG-2 couple the storage nodes SN, SNB respectively to the bit lines BL, BLB in response to a voltage applied to the gates of the pass-gate transistors PG-1, PG-2 by the word line WL.

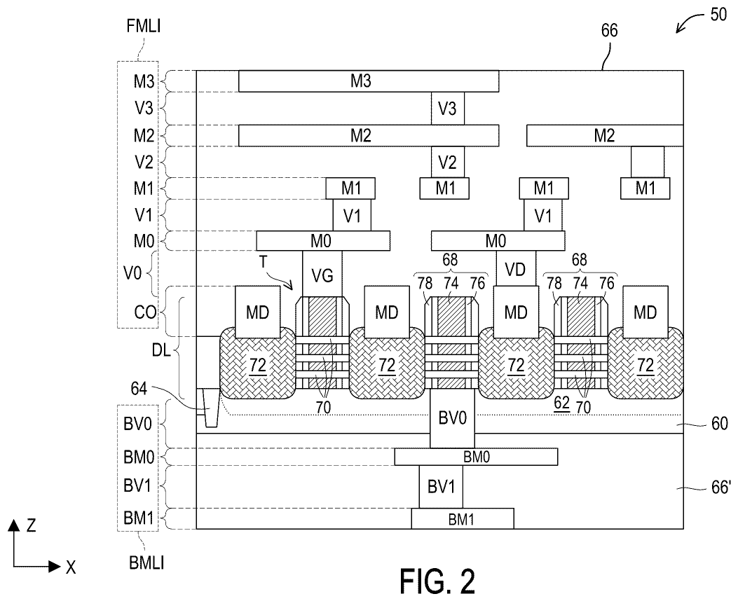

FIG. 2 is a fragmentary diagrammatic cross-sectional view of a semiconductor device 50 including various layers (levels) that can be fabricated over a semiconductor substrate (or wafer) 60 to form a portion of a memory device that includes an SRAM cell, such as the SRAM cell 10 of FIG. 1, according to various aspects of the present disclosure. As represented in FIG. 2, the various layers include a device layer DL, a frontside multilayer interconnect structure (FMLI) disposed over the device layer DL, and a backside multilayer interconnect structure (BMLI) disposed under the device layer DL. Device layer DL includes devices (e.g., transistors, resistors, capacitors, and/or inductors) and/or device components (e.g., doped wells, gate structures, and/or source/drain features). In some embodiments, device layer DL includes substrate 60, doped regions 62 disposed in substrate 60 (e.g., n-wells and/or p-wells), isolation features 64, and transistors T. In the depicted embodiment, transistors T include suspended channel layers 70 and gate structures 68 disposed between source/drain features 72, where gate structures 68 wrap around the suspended channel layers 70. Each gate structure 68 has a metal gate stack formed from a gate electrode 74 disposed over a gate dielectric 76 and gate spacers 78 disposed along sidewalls of the metal gate stack.

Multilayer interconnect structures FMLI and BMLI electrically couple various devices and/or components of the device layer DL, such that the various devices and/or components can operate as specified by design requirements for the memory device. Each of the multilayer interconnect structures FMLI and BMLI may include one or more interconnect layers.

In the depicted embodiment, the FMLI includes a contact layer (CO level), a via zero layer (V0 level), a metal zero layer (M0 level), a via one layer (V1 level), a metal one layer (M1 level), a via two layer (V2 level), a metal two layer (M2 level), a via three layer (V3 level), and a metal three layer (M3 level). The present disclosure contemplates an FMLI having more or less layers and/or levels, for example, a total number of 2 to 10 metal layers (levels) of the FMLI. Each level of the FMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the FMLI, such as M0 level, are formed simultaneously. In some embodiments, conductive features at a same level of the FMLI have top surfaces that are substantially planar with one another and/or bottom surfaces that are substantially planar with one another. The CO level includes source/drain contacts (MD) disposed in a dielectric layer 66; the V0 level includes gate vias VG and source/drain contact vias VD disposed in the dielectric layer 66. The M0 level includes M0 metal lines disposed in dielectric layer 66, where gate vias VG connect gate structures to M0 metal lines, source/drain vias V0 connect source/drains to M0 metal lines, and butted contacts connect gate structures and source/drains together and to M0 metal lines. The V1 level includes V1 vias disposed in the dielectric layer 66, where V1 vias connect M0 metal lines to M1 metal lines. The M1 level includes M1 metal lines disposed in the dielectric layer 66. The V2 level includes V2 vias disposed in the dielectric layer 66, where V2 vias connect M1 lines to M2 lines. The M2 level includes M2 metal lines disposed in the dielectric layer 66. The V3 level includes V3 vias disposed in the dielectric layer 66, where V3 vias connect M2 lines to M3 lines.

In the depicted embodiment, the BMLI includes a backside via zero layer (BV0 level), a backside metal zero layer (BM0 level), a backside via one layer (BV1 level), and a backside metal one layer (BM1 level). The present disclosure contemplates an BMLI having more or less layers and/or levels, for example, a total number of 2 to 10 metal layers (levels) of the BMLI. Each level of the BMLI includes conductive features (e.g., metal lines, metal vias, and/or metal contacts) disposed in one or more dielectric layers (e.g., an interlayer dielectric (ILD) layer and a contact etch stop layer (CESL)). In some embodiments, conductive features at a same level of the BMLI, such as BM0 level, are formed simultaneously. In some embodiments, conductive features at a same level of the BMLI have top surfaces that are substantially planar with one another and/or bottom surfaces that are substantially planar with one another. The BV0 level includes vias BV0 formed under the device layer DL. For example, the vias BV0 may include one or more backside source/drain vias formed directly under the source/drain feature(s) 72 of the device layer DL and coupled to those source/drain feature(s) 72 by way of a silicide layer. The vias BV0 may include one or more backside gate vias formed directly under and in direct contact with the gate structure(s) 68 of the device layer DL. In the present disclosure, the vias BV0 may include one or more backside butted contacts directly contacting a bottom portion of a gate structure 68 and a bottom portion of a source/drain contact (MD) for electrically connecting the gate structure 68 and the respective source/drain feature(s) 72. The BM0 level includes BM0 metal lines formed under the BV0 level and disposed in the backside dielectric structure 66′. The backside gate vias connect gate structures 68 to BM0 metal lines, and the backside source/drain vias connect source/drain features 72 to BM0 metal lines. The BV1 level includes BV1 vias disposed in the backside dielectric structure 66′, where BV1 vias connect BM0 metal lines to BM1 metal lines. The BM1 level includes BM1 metal lines formed under the BV1 level.

FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the SRAM cell 10 that is discussed in further detail below.

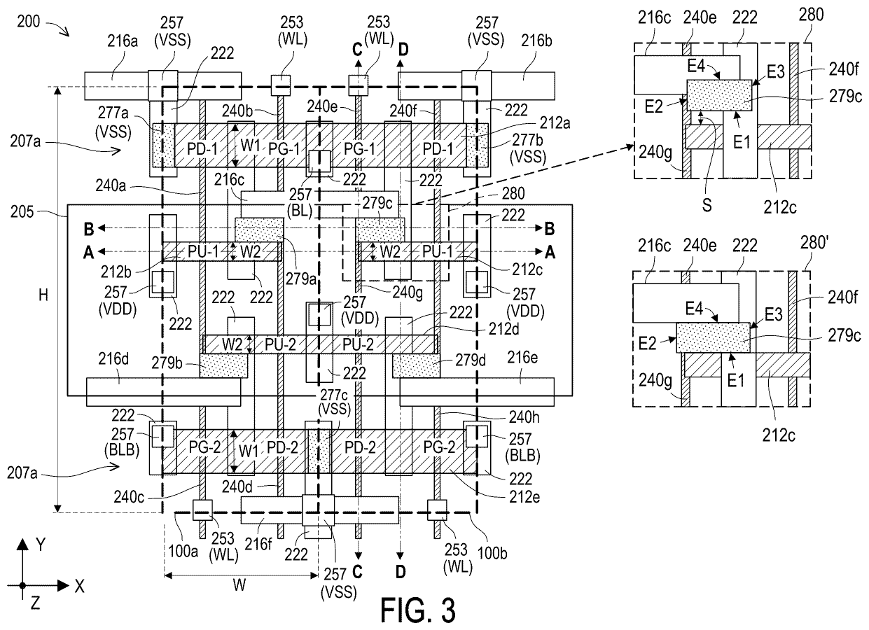

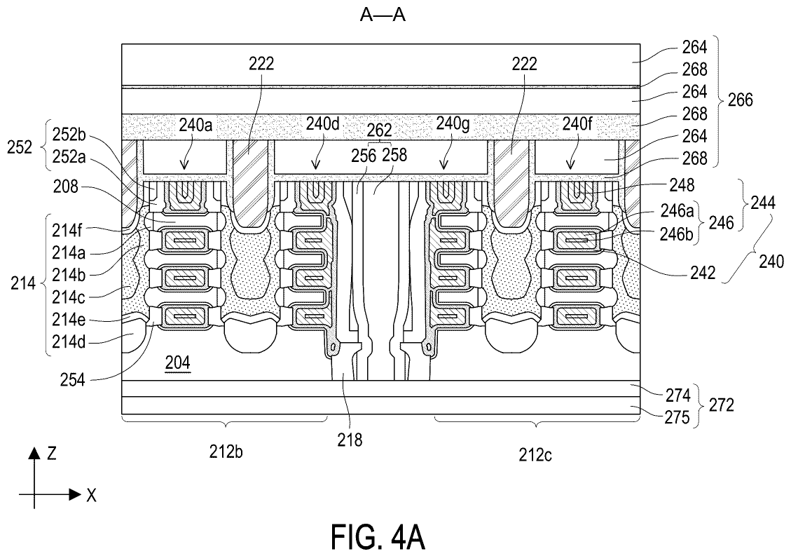

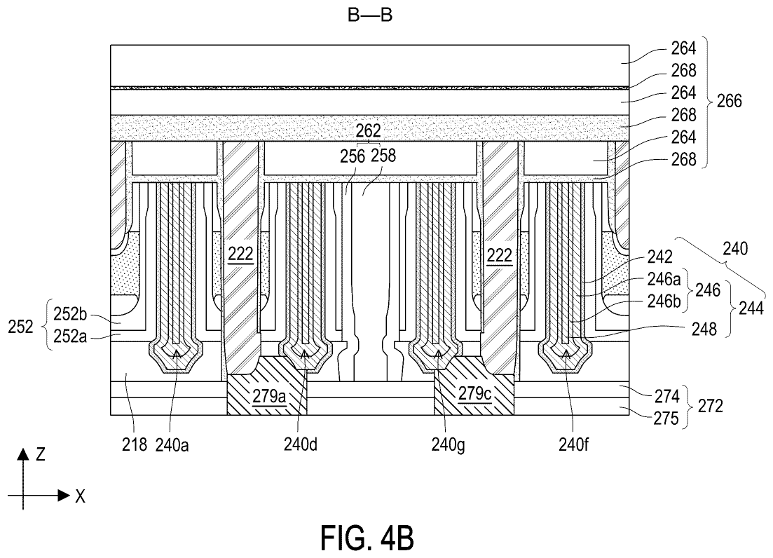

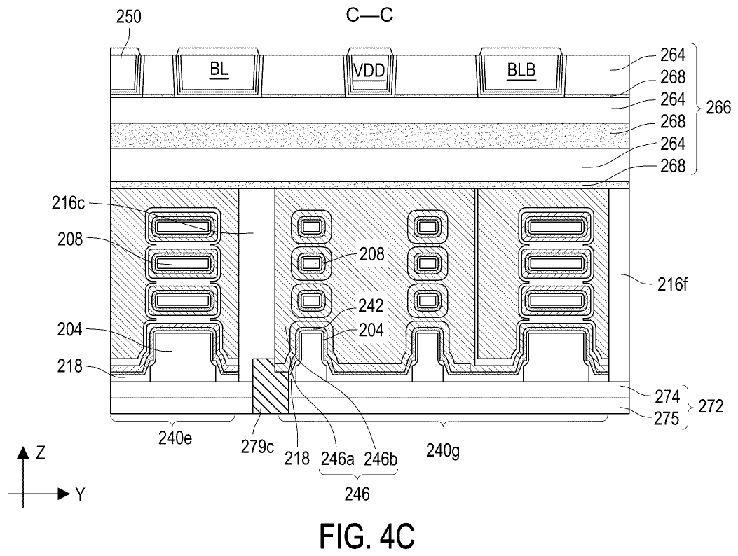

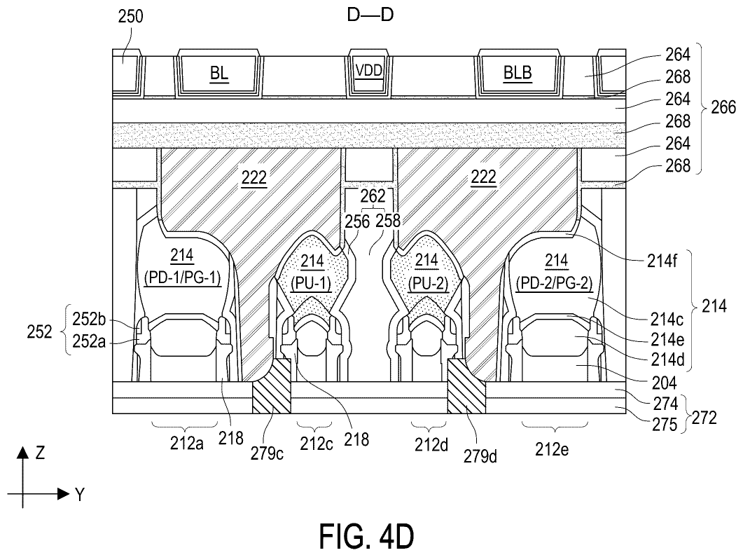

Reference is now made to FIGS. 3 and 4A-4D, collectively. FIG. 3 illustrates an exemplary layout of a semiconductor device 200, and FIGS. 4A, 4B, 4C, and 4D illustrate cross-sectional views of the semiconductor device 200 taken along lines A-A, B-B, C-C, and D-D in FIG. 3, respectively, in accordance with some embodiments of the present disclosure. In some embodiments, the semiconductor device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

The illustrated portion of the layout of the semiconductor device 200 includes two SRAM cells 100a and 100b (collectively as SRAM cells 100), which may be a portion of a larger SRAM array, according to the present disclosure. The SRAM cells 100 each may be implemented as the SRAM cell 10 in FIG. 1. The cell boundary of the SRAM cell 100 is a rectangular box that is longer in the Y-direction than in the X-direction, for example, about 2 times to about 6 times longer. The first dimension of the cell boundary along the X-direction is denoted as a cell width W, and the second dimension of the cell boundary along the Y-direction is denoted as a cell height H. Where the SRAM cell 100 is repeated in a memory array, the cell width W may represent and be referred to as a memory cell pitch in the memory array along the X-direction, and the cell height H may represent and be referred to as a memory cell pitch in the memory array along the Y-direction. In the illustrated embodiment, the cell width W is two times a poly pitch. A poly pitch refers to a minimum center-to-center distance between two adjacent gate structures along the X-direction. The two adjacent SRAM cells 100a and 100b are line symmetric with respect to a common boundary along the Y-direction.

The semiconductor device 200 includes multiple active regions 212 (including active regions 212a, 212b, 212c, 212d, and 212e) each oriented lengthwise along the X-direction and multiple gate stacks (or gate structures) 240 (including gate stacks 240a, 240b, 240c, 240d, 240e, 240f, 240g, 240h) oriented lengthwise along the Y-direction. An active region for a transistor refers to the area where a source region, a drain region, and a channel region under a gate structure of the transistor are formed. An active region is also referred to as an “oxide-definition (OD) region” in the context. In the illustrated embodiment, the active regions 212b, 212c, and 212d are p-type active regions and are disposed over an N-well region 205; the active regions 212a and 212e are n-type active regions and are disposed over two P-well regions 207a and 207b, respectively. The P-well regions 207a and 207b sandwich the N-well region 205 along the Y-direction. In some embodiments, the active regions 212 are fin-like structures and are also referred to as fin-like structures 212.

The gate stack 240a is disposed over the active regions 212a, 212b, and 212d; the gate stack 240b is disposed over the active region 212a; the gate stack 240c is disposed over the active region 212e; the gate stack 240d is disposed over the active regions 212b, 212d, and 212e; the gate stack 240e is disposed over the active region 212a; the gate stack 240f is disposed over the active regions 212a, 212c, and 212d; the gate stack 240g is disposed over the active regions 212c, 212d, and 212e; and the gate stack 240h is disposed over the active region 212e. At intersections of the active regions 212 and the gate stacks 240, transistors (e.g., pull-up transistors PU-1 and PU-2, pull-down transistors PD-1 and PD-2, pass-gate transistors PG-1 and PG-2) are formed. In the context of a GAA transistor formed at an intersection of an active region 212 and a gate stack 240, the active region 212 includes elongated nanostructures 208 (also referred to as channel members or channel layers) vertically stacked in channel regions defined in the active region 212 and above a semiconductor base 204 of the active region 212. In some embodiments, portions of the active regions 212 that are not covered by the gate stacks 240 serve as the source/drain regions. Source/drain features 214 are formed in source/drain regions defined in the active region 212 and over the semiconductor base 204. The source/drain features 214 abut two opposing ends of the channel layers 208.

Different active regions 212 in different transistors of the SRAM cell 100 may have different widths (e.g., dimensions measured in the Y-direction) in order to optimize device performance. In more detail, the active region 212a of the pull-down transistor PD-1 and the pass-gate transistor PG-1 has a width W1, the active region 212b or active region 212c of the pull-up transistor PU-1 has a width W2, the active region 212d of the pull-up transistor PU-2 has a width W2, and the active region 212e of the pass-gate PG-2 and the pull-down transistor PD-2 has a width W1. The widths W1 and W2 may also be measured in portions of the active regions corresponding to the channel regions. In other words, these portions of the active regions (from which the widths W1 and W2 are measured) are the channel regions (e.g., the vertically-stacked nanostructures 208 of GAA devices) of the transistors. To optimize SRAM performance, in some embodiments, the width W1 is configured to be greater than the width W2 (W1>W2), as an effort to balance the speed among the n-type transistors and the p-type transistors. In some embodiments, a ratio of W1/W2 may range from about 1.1 to about 3. In some other embodiments, the widths W1 and W2 may be the same (W1=W2).

Each of the source/drain features 214 may be suitable for forming a p-type device or alternatively an n-type device. The p-type source/drain features of p-type transistors (e.g., the pull-up transistors PU-1 and PU-2) may include one or more epitaxial layers of silicon germanium doped with a p-type dopant such as boron, germanium, indium, and/or other p-type dopants. The n-type source/drain features of n-type transistors (e.g., the pass-gate transistors PG-1, PG-2, the pull-down transistors PD-1, PD-2) may include one or more epitaxial layers of silicon or silicon carbon doped with an n-type dopant such as arsenic, phosphorus, and/or other n-type dopant. In the illustrated embodiment as shown in FIGS. 4A and 4D, the source/drain feature 214 is a multi-layer structure including epitaxial layers 214a, 214b, and 214c. The epitaxial layers 214a, 214b, and 214c differ in dopant concentrations with a dopant concentration gradient increasing from the epitaxial layers 214a to 214c. The epitaxial layer 214a is in direct contact with end portions of the channel layers 208. The epitaxial layer 214b separates the epitaxial layer 214c from contacting the epitaxial layer 214a. The source/drain feature 214 may further include an un-doped epitaxial layer 214d underneath the epitaxial layers 214b/214c and a dielectric film 214e interposing the un-doped epitaxial layer 214d and the epitaxial layers 214b/214c. The un-doped epitaxial layer 214d and the dielectric film 214e exhibit high resistivity and suppress leakage current from the source/drain feature 214 into the semiconductor base 204. In some embodiments, the source/drain feature 214 further includes a silicide feature 214f atop the epitaxial layers 214b/214c. The silicide feature 214f reduces resistivity between the source/drain feature 214 and the source/drain contact 222 formed thereon. The silicide feature 214f may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

The gate stacks 240 may include a gate dielectric layer 242 and a gate electrode layer 244 formed over the gate dielectric layer 242 (shown in FIGS. 4A-4C). The gate dielectric layer 242 may further include an interfacial layer formed on surfaces of the channel layers 208 interfacing the gate stacks 240 and a high-k dielectric layer formed over the interfacial layer 238. The interfacial layer may include silicon dioxide, silicon oxynitride, or other suitable materials. The high-k dielectric layer may include a high-k dielectric material such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. High-k dielectric material generally refers to dielectric materials having a high dielectric constant, for example, greater than that of silicon oxide (k≈3.9). In some embodiments, the gate electrode layer 244 may further includes a work function layer 246 that is an n-type or a p-type work function layer and a metal fill layer 248 over the work function layer 246. For example, an n-type work function layer may comprise a metal with sufficiently low effective work function, and a p-type work function layer may comprise a metal with a sufficiently large effective work function. For example, an n-type work function layer may include Ta, titanium aluminum (TiAl), titanium aluminum carbide (TiAlC), titanium aluminum oxide (TiAlO), TiAlN, or combinations thereof. For example, a p-type work function layer may include TiN, TaN, WN, or combinations thereof. In some embodiments, the work function layer 246 may include a multi-layer structure, such as a first work function layer 246a and a second work function layer 246b. For example, the first work function layer 246a may comprise a metal such as titanium, aluminum, tantalum carbide, tantalum carbide nitride, tantalum silicon nitride, or combinations thereof, and the second work function layer 246b may comprise a metal such as titanium nitride, tantalum nitride, ruthenium, molybdenum, tungsten, platinum, or combinations thereof. In some embodiments, the metal fill layer 248 includes aluminum, tungsten, cobalt, copper, and/or other suitable materials. Since the gate stacks 240 include a high-k dielectric layer and metal layer(s), the gate stacks 240 are also referred to as high-k metal gates.

The semiconductor device 200 further includes a plurality of gate-cut dielectric features 216 (including gate-cut dielectric features 216a, 216b, 216c, 216d, 216e, and 216f). The gate-cut dielectric feature 216 divides an otherwise continuous gate structure into two isolated segments. For example, the gate-cut dielectric feature 216c divides the gate stack 240b from the gate stack 240d and divides the gate stack 240e from the gate stack 240g; the gate-cut dielectric feature 216d divides the gate stack 240a from the gate stack 240c; and the gate-cut dielectric feature 216e divides the gate stack 240f from the gate stack 240h. The gate-cut dielectric features 216 is formed by filling a corresponding cut-metal-gate (CMG) trench in the position of the gate-cut dielectric feature. A CMG process refers to a fabrication process where after a gate stack (e.g., a high-k metal gate) replaces a dummy gate structure (e.g., a polysilicon gate), the gate stack is cut (e.g., by an etching process) to separate the previously continuous gate stack into two or more separated gate segments. Each gate segment functions as a metal gate for an individual transistor. An isolation material is subsequently filled into trenches between adjacent portions of the metal gate. These trenches are referred to as cut-metal-gate trenches, or CMG trenches. The dielectric material filling a CMG trench for isolation is referred to as a CMG feature. Therefore, the gate-cut dielectric feature 216 is also referred to as a CMG feature. To ensure a gate stack would be completely cut, a CMG feature often further extends into adjacent areas, such as dielectric layers filling space between the metal gates. A CMG feature often have an elongated shape in a top view. In the illustrated embodiment, each of the gate-cut dielectric features 216 extends lengthwise along the X-direction. A gate-cut dielectric feature 216 may extend through SRAM cell boundary and be shared by adjacent SRAM cells 100. In the illustrated embodiment, each of the gate-cut dielectric features 216c, 216d, and 216e is disposed above an interface between the N-well and P-well regions.

The semiconductor device 200 also includes an isolation feature 218 (shown in FIGS. 4A-4D) formed around each active region 212 to isolate two adjacent active regions 212. The isolation feature 218 may also be referred to as a shallow trench isolation (STI) feature and may include silicon oxide, silicon oxynitride, fluorine-doped silicate glass (FSG), a low-k dielectric, combinations thereof, and/or other suitable materials.

The semiconductor device 200 also includes inner spacers 254 (shown in FIG. 4A) disposed between the source/drain features 214 and the adjacent gate stacks 240. The inner spacers 254 isolates the source/drain features 214 from the adjacent gate stacks 240. In some embodiments, the inner spacers 254 include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the inner spacers 254 include a low-k dielectric material, such as those described herein.

The semiconductor device 200 also includes gate spacers 252 (shown in FIGS. 4A, 4B, and 4D) disposed on sidewalls of the gate stacks 240. The gate spacers 252 may include a dielectric material, such as an oxygen-containing material (e.g., silicon oxide, silicon oxycarbide, aluminum oxide, aluminum oxynitride, hafnium oxide, titanium oxide, zirconium aluminum oxide, zinc oxide, tantalum oxide, lanthanum oxide, yttrium oxide, silicon oxycarbonitride, etc.), a nitrogen-containing material (e.g., tantalum carbonitride, silicon nitride (SiN), zirconium nitride, silicon carbonitride, etc.), a silicon-containing material (e.g., hafnium silicide, silicon, zirconium silicide, etc.), other suitable materials, or combinations thereof. The gate spacers 252 may be a single layered structure or a multi-layered structure (such as depicted layers 252a and 252b). As shown in FIG. 4D, the gate spacers 252 may also extend to the source/drain regions of the active regions 212.

The semiconductor device 200 also includes a dielectric structure 262 (shown in FIGS. 4A, 4B, and 4D) disposed over the source/drain features 214. The dielectric structure 262 may include a contact etch-stop layer (CESL) 256 and an interlayer dielectric (ILD) layer 258 formed over the CESL 256. The ILD layer 258 includes a dielectric material, such as tetraethylorthosilicate (TEOS), silicon oxide, a low-k dielectric material, doped silicon oxide such as borophosphosilicate glass (BPSG), phosphosilicate glass (PSG), FSG, boron doped silicate glass (BSG), other suitable dielectric materials, or combinations thereof. The ILD layer 258 may include a multi-layer structure having multiple dielectric materials. The CESL 256 may comprise silicon nitride, silicon oxynitride, silicon nitride with oxygen or carbon elements, other suitable materials, or combinations thereof. As shown in FIG. 4A, the dielectric structure 262 also fills the trench between two adjacent active regions (such as active regions 212b and 212c) as an isolation feature separating two adjacent active regions. The portions of the dielectric structure 262 filling the trench between two adjacent active regions is also referred to as fin-cut features.

The semiconductor device 200 also includes a frontside dielectric structure 266 (shown in FIGS. 4A-4D) disposed over the dielectric structure 262, the gate stacks 240, the gate spacers 252, and the gate-cut dielectric features 216. In some embodiments, the frontside dielectric structure 266 includes multiple dielectric layers 264 and etch stop layers (ESLs) 268. The ESLs 268 may include La₂O₃, Al₂O₃, SiOCN, SiOC, SiCN, SiN, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material. The dielectric layers 264 may include SiO₂, tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof.

The semiconductor device 200 also includes source/drain contacts 222 disposed over and in electrical coupling with the source/drain features 214. In an embodiment, the source/drain contacts 222 may include a conductive barrier layer and a metal fill layer over the conductive barrier layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The metal fill layer may include tungsten (W), cobalt (Co), molybdenum (Mo), ruthenium (Ru), or other metals. Some of the source/drain contacts 222 land on and electrically connect multiple source/drain features and are referred to as long contact in some instances. For example, as shown in FIG. 4D, the source/drain contact 222 on the left electrically connects the n-type source/drain feature 214 of the transistors PD-1 and PG-1 and the p-type source/drain feature 214 of the transistor PU-1; and the source/drain contact 222 on the right electrically connects the n-type source/drain feature 214 of the transistors PD-2 and PG-2 and the p-type source/drain feature 214 of the transistor PU-2. Also as depicted in FIGS. 4B and 4D, the source/drain contacts 222 may extend through the dielectric structure 262 and a portion of the dielectric structure 266 (e.g., a dielectric layer 264 and an ESL 268).

The semiconductor device 200 also includes gate vias 253 (shown in FIG. 3) that connect the gate stacks 240 and word lines (WL) of the metal lines 250 (shown in FIGS. 4C and 4D). The gate vias 253 may be embedded in the dielectric structure 266 as depicted. The gate vias 253 may include similar materials and may be formed similarly as the source/drain contacts 222. The semiconductor device 200 also includes source/drain contact vias 257 (shown in FIG. 3). The source/drain contact vias 257 may be embedded in the dielectric structure 266 and connect the source/drain contacts 222 and metal lines 250 (e.g., bit line (BL), bit line bar (BLB), VDD, and VSS). The source/drain contact vias 257 may include similar materials and may be formed similarly as the gate vias 253.

The semiconductor device 200 also includes a backside dielectric structure 272 (shown in FIGS. 4A-4D) disposed on the backside of the semiconductor device 200. In some embodiments, the backside dielectric structure 272 includes multiple etch stop layers (ESLs) 274 and dielectric layers 275. The ESLs 274 may include La₂O₃, Al₂O₃, SiOCN, SiOC, SiCN, SiN, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material. The dielectric layers 275 may include SiO₂, tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. In FIGS. 4A-4D, only one pair of ESL 274 and dielectric layer 275 in the backside dielectric structure 276 are shown, which correspond to the dielectric layer at the BV0 level (FIG. 2). The backside dielectric structure 276 may include multiple pairs of dielectric layer 275 and ESL 274 for other backside layers, such as BM0, BV1, BM1 levels and so on.

In the BV0 level, the semiconductor device 200 includes two types of backside contacts, namely backside source/drain contacts 277 (including backside source/drain contacts 277a, 277b, and 277c) disposed directly under respective active regions 212 and backside butted contacts 279 (including backside butted contacts 279a, 279b, 279c, and 279d) offset from respective active regions 212. Each of the backside contacts may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals. In one embodiment, the backside contacts include tungsten (W).

As shown in FIG. 3, the illustrated portion of the semiconductor device 200 includes two backside source/drain contacts 277a and 277b disposed on the backside of the active region 212a and one backside source/drain contact 277c disposed on the backside of the active region 212e. Each of the backside source/drain contacts 277 electrically couple to the corresponding source/drain contact 222 and the frontside source/drain contact via 257 through the respective source/drain features 214 therebetween. Similar to functions of the corresponding frontside source/drain contact vias 257, the backside source/drain contacts 277 electrically couple the source regions of the pull-down transistors PD-1 and PD-2 to the electrical ground VSS. Underneath the BV0 level, the BM0 level includes a plurality of backside VSS lines (not shown). The backside source/drain contacts 277 may have the same dimension along the Y-direction as the active regions 212a and 212e (e.g., W1). This is due to one exemplary backside manufacturing flow in which the backside vias is formed by etching a fin-shape semiconductor base in an active region from the backside to form a backside trench and filling the backside trench with conductive materials. Therefore, the backside source/drain contacts 277 inherit the width of the respective active regions. Further, the backside source/drain contacts 277 may have the same dimension along the X-direction as the source/drain contacts 222. In the illustrated embodiment, the backside source/drain contacts 277 has an elongated shape with a lengthwise direction along the Y-direction.

As shown in FIGS. 3 and 4B-4D, the illustrated portion of the semiconductor device 200 includes four backside butted contacts 279. Each of the backside butted contacts 279 at least partially lands on the bottom surface of the respective gate stack 240 and at least partially lands on the bottom surface of the respective source/drain contact 222. Therefore, the backside butted contact 279 provides electrical connection between the respective gate stack 240 and the common source/drain region of the PD-1/PG-1/PU-1 transistors or PD-2/PG-2/PU-2 transistors through the respective source/drain contact 222 and source/drain feature 214. Particularly, there is no overlapping area between the backside butted contact 279 and the respective active region 212 from a top view, which ensures that the respective source/drain feature 214 is not exposed and thus not suffered from etching loss and volume loss during the formation of the backside butted contact 269.

A region 280 containing a backside butted contact 279c is enlarged to illustrate further details. The backside butted contact 279c has an elongated shape with a lengthwise direction along the X-direction. Edges between the backside butted contact 279c and the active region 212c are spaced apart by a distance S along the Y-direction. The backside butted contact 279c at least partially overlaps with the width of the gate stack 240g along the X-direction and at least partially overlaps with the width of the source/drain contact 222 along the X-direction. As shown in FIGS. 4B and 4C, the gate dielectric layer 242 of the gate stack 240g is partially removed, and the gate electrode layer 244 is exposed and in physical contact with the backside butted contact 279c. In the illustrated embodiment, the first work function layer 246a is exposed and in physical contact with the backside butted contact 279c. In an alternative embodiment, the removal of the gate dielectric layer 242 may also partially remove the first work function layer 246a, and the second work function layer 246b is exposed and in physical contact with the backside butted contact 279c. In yet another alternative embodiment, the removal of the gate dielectric layer 242 may also partially remove the work function layer 246, and the metal fill layer 248 is exposed and in physical contact with the backside butted contact 279c. As shown in FIG. 4C, a portion of the backside butted contact 279c also lands on the bottom surface of the gate-cut dielectric feature 216c. As shown in FIGS. 4B and 4D, the backside butted contact 279c lands on the bottom surface of the source/drain contact 222. Therefore, an electrical path is established between the gate stack 240g with the common source/drain region of the PD-1/PG-1/PU-1 transistors of the SRAM cell 100b, which is through the bottom surface of the gate stack 240g, the backside butted contact 279c, the bottom surface of the source/drain contact 222, the interface between the source/drain contact 222 and the top surface of the source/drain feature 214 (may through silicide feature 214f if presented), and the source/drain feature 214, in sequence. It is understood that similar electrical paths are also established for the backside butted contacts 279a, 279b, and 279d, respectively, which are not repeated for the sake of simplicity.

Still referring to the enlarged region 280 as depicted in FIG. 3, the position and size of the backside butted contact 279c is defined by its four edges E1, E2, E3, and E4. The four edges each can be independently adjusted to determine the position and size of the backside butted contact 279c based on device performance needs as long as the following conditions are still met. First is that the distance S between the edge E1 and the active region 212c is at least zero (S≥0). That is, the edge E1 is at most aligned with (when S=0) the opposing edge of the active region 212c without causing an overlapping area. No overlapping area safeguards the bottom surface of the source/drain feature 214 from being exposed during the formation of the backside butted contact 279c and thus from losing volume due to etching loss. When the edge E1 is aligned with (when S=0) the opposing edge of the active region 212c, the sidewalls of the backside butted contact 279c and the source/drain feature 214 may directly interface with each other. When the edge E1 is spaced part (when S>0) from the opposing edge of the active region 212c, the sidewalls of the backside butted contact 279c and the source/drain feature 214 are interposed by dielectric layers, such as STI feature 218, gate spacers 252, and/or the dielectric structures 262 (including CESL 256 and/or ILD 258). Second is that there is overlapping between the gate stack 240g and the backside butted contact 279c, which ensures electrical contact therebetween. The edge E2 may be directly under the gate stack 240g for a partial overlapping or beyond for a full overlapping with the width of the gate stack 240g. Third is that there is overlapping between the source/drain contact 222 and the backside butted contact 279c, which ensures electrical contact therebetween. The edge E3 may be directly under the source/drain contact 222 for a partial overlapping or beyond for a full overlapping with the width of the source/drain contact 222. Fourth is that the edge E4 is not positioned beyond the edge of the gate-cut dielectric feature 216c interfacing the gate stack 240e to avoid overlapping and thus electrical short between the backside butted contact 279c and the other gate stack 240e.

An alternative embodiment of the enlarged region, denoted as 280′, is also depicted in FIG. 3 to illustrate one of the combinations of the positions of the edges E1, E2, E3, and E4. In the enlarged region 280′, the edge E1 is aligned with (when S=0) the opposing edge of the active region 212c without causing an overlapping area; the edge E2 is beyond an edge of the gate stack 240g for a full overlapping with the width of the gate stack 240g, such that in a cross-sectional view (B-B) the whole bottom surface of the gate stack 240g is in physical contact with the backside butted contact 279c; the edge E3 is directly under the source/drain contact 222 for a partial overlapping; and the edge E4 is aligned with the opposing edge of the gate-cut dielectric feature 216c without causing an overlapping area. It is understood that the enlarged region 280′ is one of the alternative embodiments in compliance with the four conditions for the edges E1, E2, E3, and E4 as discussed above. Not all the alternative embodiments are enumerated for the sake of simplicity.

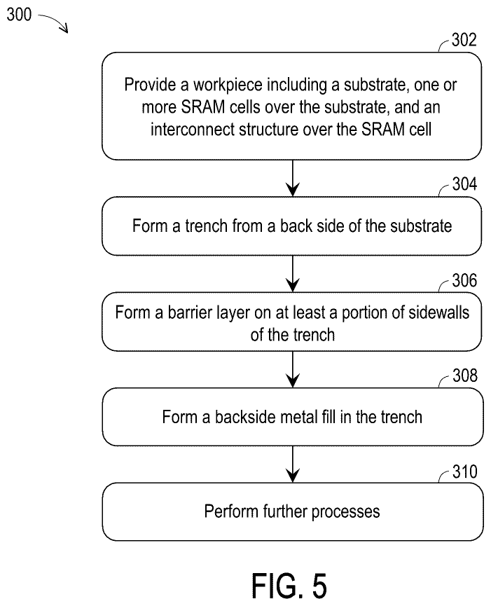

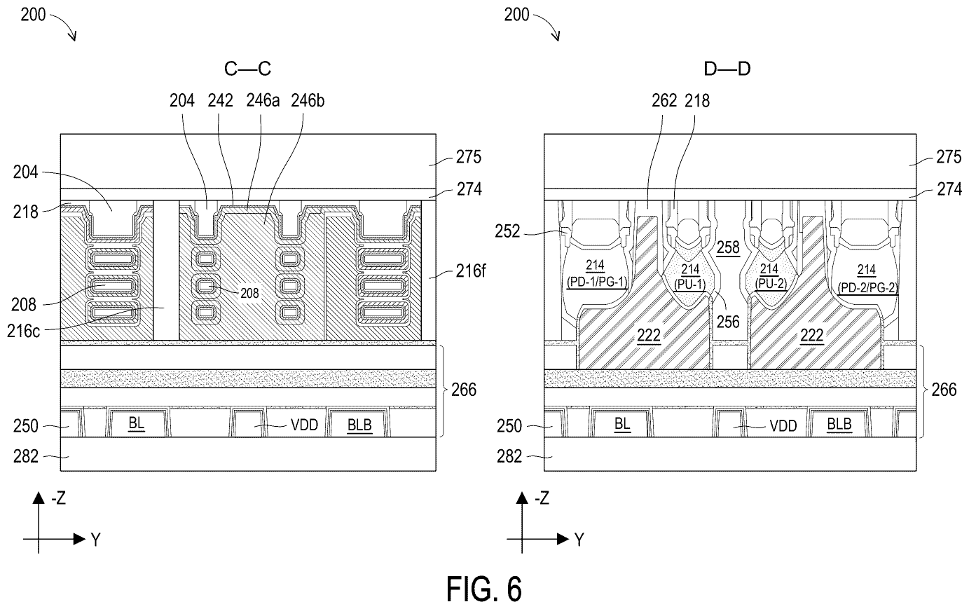

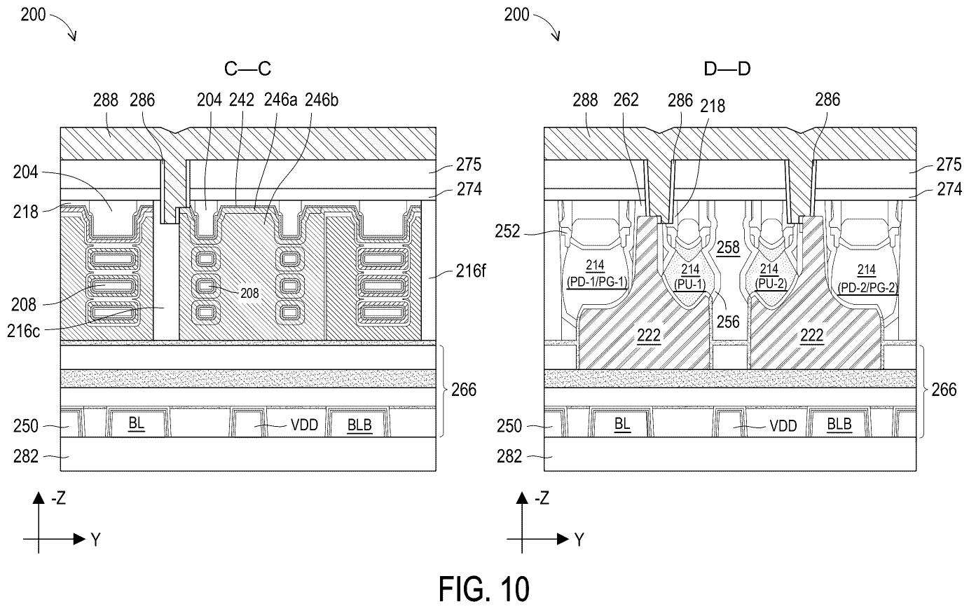

Reference is now made to FIG. 5. FIG. 5 is a flowchart illustrating a method 300 of forming the semiconductor device 200 as shown in FIGS. 3 and 4A-4D from a workpiece according to embodiments of the present disclosure. Method 300 is merely an example and is not intended to limit the present disclosure to what is explicitly illustrated in method 300. Additional steps can be provided before, during, and after method 300, and some steps described can be replaced, eliminated, or moved around for additional embodiments of the method. Not all steps are described herein in detail for reasons of simplicity. Method 300 is described below in conjunction with FIGS. 6-14, each of which includes two cross-sectional views taken along the lines C-C and D-D of the semiconductor device 200 in FIG. 3 at different stages of fabrication according to embodiments of the method 300 in FIG. 5. The semiconductor device 200 during the fabrication stages is also referred to as workpiece 200.

Referring to FIGS. 5 and 6, method 300 includes a block 302 where the workpiece 200 is mounted on a carrier wafer 282 with its top surface and flipped upside down. The negative sign in the axis “−Z” denotes the direction.

Each of the active regions 212 includes a semiconductor base 204 and stacks of nanostructures 208 vertically stacked and suspended over the semiconductor base 204. In embodiments, the semiconductor bases 204 include silicon, silicon germanium, germanium, or other suitable semiconductor, and may be doped with n-type or p-type dopants. The active regions 212 may be patterned by any suitable method. For example, the active regions 212 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used as a masking element for patterning the active regions 212. For example, the masking element may be used for etching recesses into semiconductor layers over or in the semiconductor substrate, leaving the active regions 212 on the semiconductor substrate. The etching process may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Numerous other embodiments of methods to form the active regions 212 may be suitable.

The nanostructures 208 in a stack connect two source/drain features 214 and function as channel layers of the GAA transistors. Thus, the nanostructures 208 may also be referred to as the channel layers 208. The nanostructures 208 may include a semiconductor material suitable for transistor channels, such as silicon, silicon germanium, or other semiconductor material(s). The nanostructures 208 may be in the shape of rods, bars, sheets, or other shapes in various embodiments. In an embodiment, the nanostructures 208 are initially part of a stack of semiconductor layers that include the nanostructures 208 and other sacrificial semiconductor layers alternately stacked layer-by-layer. The sacrificial semiconductor layers and the nanostructures 208 include different material compositions (such as different semiconductor materials, different constituent atomic percentages, and/or different constituent weight percentages) to achieve etching selectivity. During a gate replacement process to form the gate stacks 240, the sacrificial semiconductor layers are selectively removed, leaving the nanostructures 208 suspended over the semiconductor base 204. It is noted that three (3) nanostructures 208 are vertically stacked in the illustrated embodiment, which is for illustrative purposes only and not intended to be limiting beyond what is specifically recited in the claims. It can be appreciated that any number of nanostructures can be formed, depending on device performance needs. In some embodiments, the number of nanostructures 208 vertically stacked is between (including) 2 and 10.

The source/drain features 214 are formed in and/or over source/drain regions of the active regions 212, each being disposed adjacent to the gate stacks 240. The source/drain feature(s) 214 may refer to a source or a drain, individually or collectively dependent upon the context. The source/drain features 214 may be formed by any suitable techniques, such as etching processes followed by one or more epitaxial growth processes. In one example, one or more etching processes are performed to remove portions of the active regions 212 to form recesses (not shown) in the source/drain regions. A cleaning process may be performed to clean the recesses with a hydrofluoric acid (HF) solution or other suitable solution. Subsequently, one or more epitaxial growth processes are performed to grow the source/drain features 214 in the recesses.

The inner spacers 254 may be formed by deposition and etching processes. For example, after source/drain trenches are etched and before the source/drain features 214 are epitaxially grown from the S/D trenches, an etch process may be used to recess the sacrificial layers between the adjacent channel layers 208 to form gaps vertically between the adjacent channel layers 208. Then, one or more dielectric materials are deposited (using CVD or ALD for example) to fill the gaps. Another etching process is performed to remove the dielectric materials outside the gaps, thereby forming the inner spacers 254.

The gate stacks 240 are formed between two source/drain features 214, disposed over and wrapping around each of the channel layers 208. The gate stacks 240 include the gate dielectric layer 242 and the gate electrode layer 244 formed over the gate dielectric layer 242. The interfacial layer in the gate dielectric layer 242 may be formed by chemical oxidation, thermal oxidation, atomic layer deposition (ALD), chemical vapor deposition (CVD), and/or other suitable methods. The high-k dielectric layer in the gate dielectric layer 242 may be formed by ALD, CVD, metal-organic CVD (MOCVD), PVD, thermal oxidation, and/or other suitable methods. The gate electrode layer 244 may be formed by CVD, PVD, plating, and/or other suitable processes. In some embodiments, the gate stacks 240 are formed after other components of the workpiece 200 (e.g., the source/drain features 214) are fabricated. Such process is generally referred to as a gate replacement process, which includes forming dummy gate structures (not depicted) as a placeholder for the gate stacks 240, forming the source/drain features 214, forming dielectric structures 262 over the dummy gate structures and the source/drain features 214, planarizing the semiconductor device 200 to expose top surfaces of the dummy gate structures, removing the dummy gate structures in the dielectric structure 262 to form trenches that expose the channel regions of the active regions 212, removing the sacrificial layers for channel release, and forming the gate stacks 240 in the trenches and around the channel layers 208 to complete the gate replacement process.

The composition of the gate spacers 252 is distinct from that of the surrounding dielectric components (e.g., the dielectric structure 262), such that an etching selectivity may exist between the gate spacers 252 and the surrounding dielectric components. In an embodiment, the gate spacers 252 include SiN. The gate spacers 252 may be formed by first depositing a blanket of spacer material over the workpiece 200, and then performing an anisotropic etching process to remove portions of the spacer material to form the gate spacers 252.

The CESL 256 may be formed by CVD, PVD, ALD, other suitable methods, or combinations thereof. The ILD layer 258 may be formed by a deposition process such as, for example, CVD, flowable CVD (FCVD), spin-on-glass (SOG), other suitable methods, or combinations thereof. The ILD layer 258 may be deposited after the deposition of the CESL 256.

The gate-cut dielectric features 216 may be formed by patterning process to form trenches and deposition process to fill in the trenches with one or more dielectric materials. The patterning process includes lithography process and etching process and may use a hard mask to define the regions for the gate-cut dielectric features 216. The etching process may include wet etch, dry etch, or a combination thereof to etch through the conductive materials of the long metal gate structure. The etching process may use one or more etchant. A CMP may be performed after the deposition process to remove the excessive materials of the gate-cut dielectric feature 216 deposited on the dielectric structures 262 and the gate stacks 240, and planarize the top surface of the workpiece 200.

The ESL 274 and the dielectric layer 275 are deposited on the backside of the workpiece 200. The ESL 274 may be formed by CVD, PVD, ALD, or other suitable methods. The dielectric layers 264 may be formed by PECVD (plasma enhanced CVD), FCVD (flowable CVD), or other suitable methods. A thickness of the ESL 274 may range from about 5 nm to about 15 nm. A thickness of the dielectric layer 275 may range from about 30 nm to about 50 nm. Prior to the deposition of the ESL 274 and the dielectric layer 275, method 300 may include thinning down the workpiece 200 from the backside of the workpiece 200. In some embodiments, upon completion of the thinning down, the semiconductor bases 204, the gate-cut dielectric feature 216, the STI features 218, and the dielectric structures 262 are exposed from the backside of the workpiece 200. The thinning process may include a mechanical grinding process and/or a chemical thinning process. A substantial amount of substrate material may be first removed from the semiconductor substrate during a mechanical grinding process. Afterwards, a chemical thinning process may apply an etching chemical to the backside of the semiconductor substrate to further thin down the semiconductor substrate until the semiconductor bases 204, the gate-cut dielectric feature 216, the STI features 218, and the dielectric structures 262 are exposed.

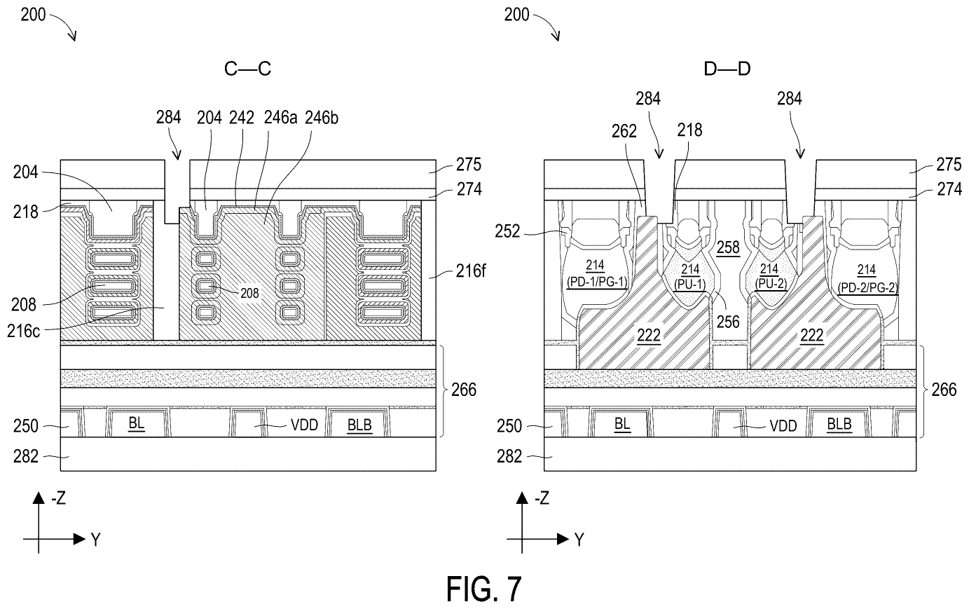

Referring to FIGS. 5 and 7, method 300 includes a block 304 where trenches 284 are formed from a backside of the semiconductor device 200. The trenches 284 are located at the same positions of the backside butted contacts 279 as shown in FIG. 3.

Forming the trenches 284 may include forming a hard mask layer (not shown) overlying the dielectric layer 275 and performing a lithography patterning and etching process to pattern the hard mask layer. The hard mask layer may include SiO, HfSi, SiOC, AlO, ZrSi, AlON, ZrO, HfO, TiO, ZrAlO, ZnO, TaO, LaO, YO, TaCN, SiN, SiOCN, Si, SiOCN, ZrN, SiCN, or other suitable materials. Then, one or more etching processes are performed using the hard mask layer as a mask to form the trenches 284. The one or more etching processes may include multiple steps and involve various etching fluids. The one or more etching processes may include dry etching, wet etching, reactive ion etching (RIE), and/or other suitable processes. For example, a dry etching process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. For example, a wet etching process may comprise etching in diluted hydrofluoric acid (DHF); potassium hydroxide (KOH) solution; ammonia; a solution containing hydrofluoric acid (HF), nitric acid (HNO₃), and/or acetic acid (CH₃COOH); or other suitable wet etchant. Due to the etching loss, the thickness of the dielectric layer 275 may reduce to about 23 nm to about 40 nm.

The trenches 284 extend through the ESL 274 and partially extend into the gate-cut dielectric features 216 and the dielectric structures 262. After the gate dielectric layer 242 is exposed in the trenches 284, the etching process further removes the exposed portion of the gate dielectric layer 242 to expose the gate electrode layer 244 in the trenches 284. The bottom portion of the source/drain contacts 222 extend between two adjacent n-type and p-type source/drain features 214. The trenches 284 also exposes the bottom surface and a portion of the sidewall surface of the bottom portion of the source/drain contact 222. The trenches 284 also exposes the dielectric structure 262 and the STI feature 218 between two adjacent n-type and p-type source/drain features 214.

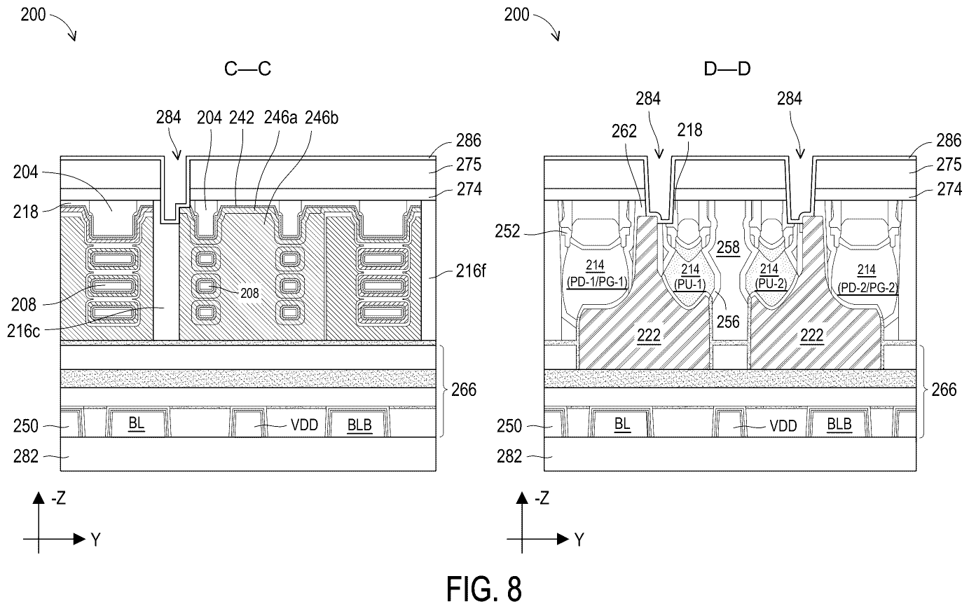

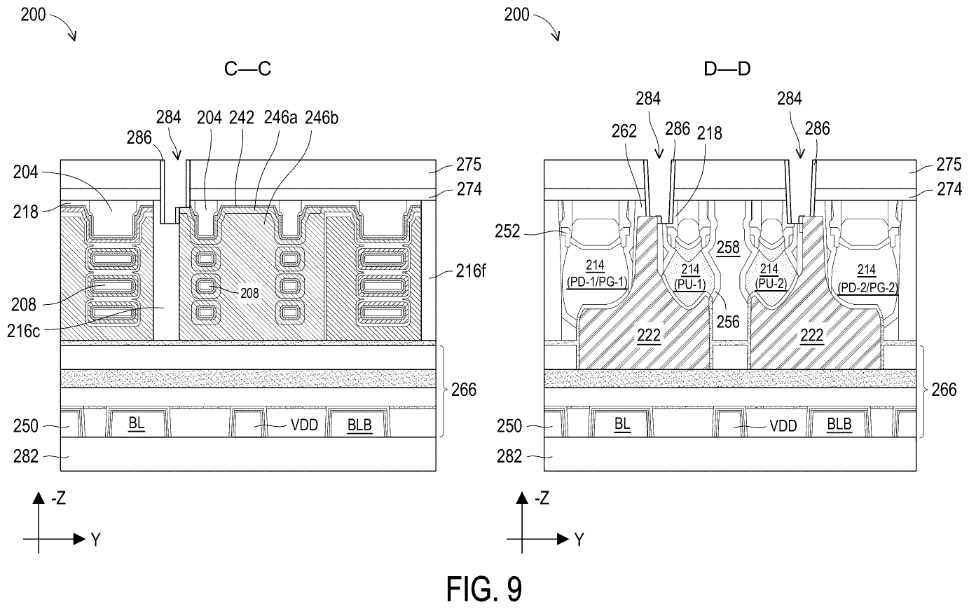

Referring to FIGS. 5 and 8-9, method 300 includes a block 306 where a barrier layer 286 is formed on sidewalls of the trenches 284. This step is optional. The barrier layer 286 may include a dielectric material such as silicon oxide, silicon nitride, silicon carbide, silicon oxynitride, SiCN films, silicon oxycarbide, SiOCN films, and/or combinations thereof. In some embodiments, the barrier layer 286 includes silicon nitride. By way of example, as shown in FIG. 8, the barrier layer 286 may be formed by blanket depositing a dielectric material layer in a conformal manner over the back side of the workpiece 200 using processes such as, a CVD process, an SACVD process, an ALD process, a PVD process, or other suitable process. In the illustrated embodiment, the deposition of the dielectric material layer is followed by an etching-back (e.g., anisotropically) process to remove the dielectric material layer from horizontal surface(s) and a top portion of sidewall surface(s) of the trench 284. In some embodiments, the etching-back process may include a wet etch process, a dry etch process, a multiple-step etch process, and/or a combination thereof. The dielectric material layer may remain on sidewalls of the trenches 284 as the barrier layer 286. The resultant structure after the etching-back process is shown in FIG. 9. The barrier layer 286 provides electrical isolation between the backside metal fill 288 (to be described below) and other features surrounding the trenches 284. In some embodiments, the deposited barrier layer 286 is first treated such that its composition is changed. In this case, the treated portion of the barrier layer 286 remains during the etching-back process and the untreated portion is removed by the etching-back process. In furtherance of the embodiments, the barrier layer 286 includes silicon oxide, and the treating process includes a tilted ion implantation using proper ions, such as nitrogen ions so that nitrogen is introduced into a bottom portion of the barrier layer 286. Thereafter, the treated portion of the barrier layer 286 is selectively removed by the etching-back process using a proper etchant such as phosphorous acid.

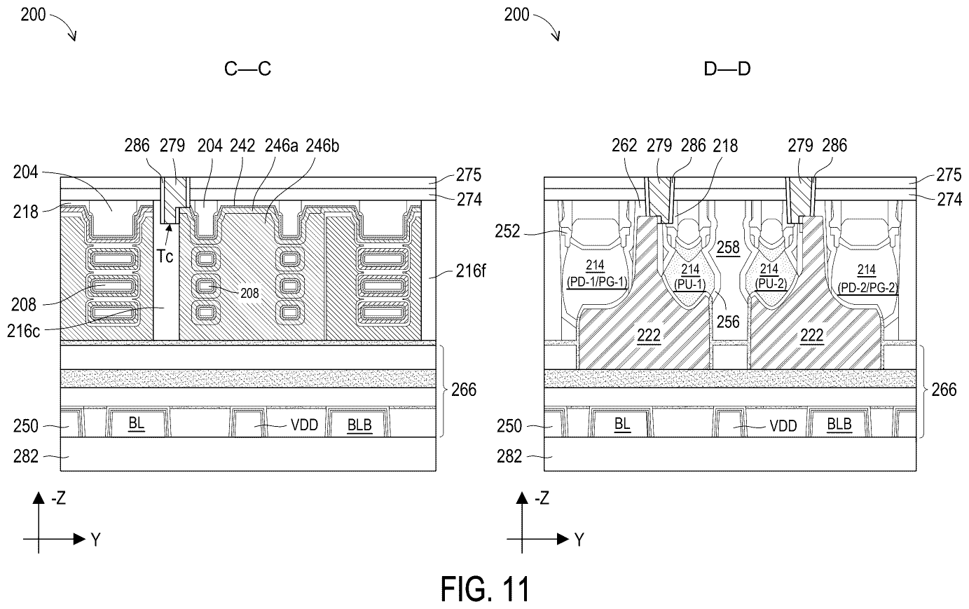

Referring to FIGS. 5 and 10-11, method 300 includes a block 308 where a backside metal fill 288 is formed in the trenches 284. The backside metal fill 288 may include tungsten (W), cobalt (Co), molybdenum (Mo), ruthenium (Ru), copper (Cu), nickel (Ni), titanium (Ti), tantalum (Ta), titanium nitride (TiN), tantalum nitride (TaN), or other metals, and may be formed by CVD, PVD, ALD, plating, or other suitable processes. In some embodiments, the backside metal fill 288 includes W. A planarization operation, such as a CMP process, is performed to remove excessive conductive material of the backside metal fill 288. The dielectric layer 275 may function as a stop layer for the planarization operation, such that the planarization operation also removes the hard mask layer. The remaining portions of the backside metal fill 288 in the trenches 284 become the backside butted contacts 279. The resultant structure after the planarization operation is shown in FIG. 11.

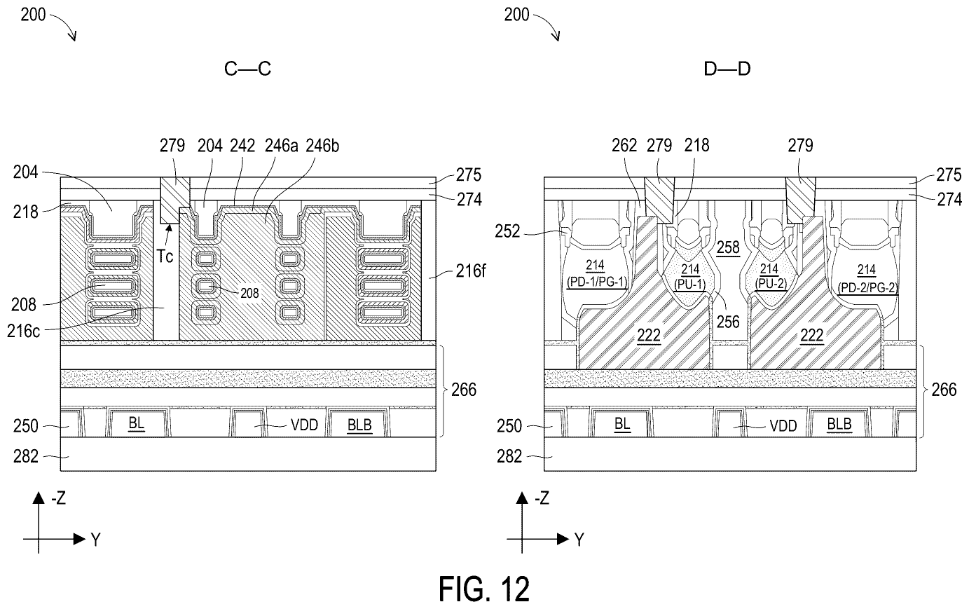

As discussed above, the barrier layer 286 is optional. By skipping the formation of the barrier layer 286, the contact area between the backside butted contacts 279 and the gate stacks 240 and the source/drain contacts 222 is increased, which reduces contact resistance. The alternative resultant structure is shown in FIG. 12.

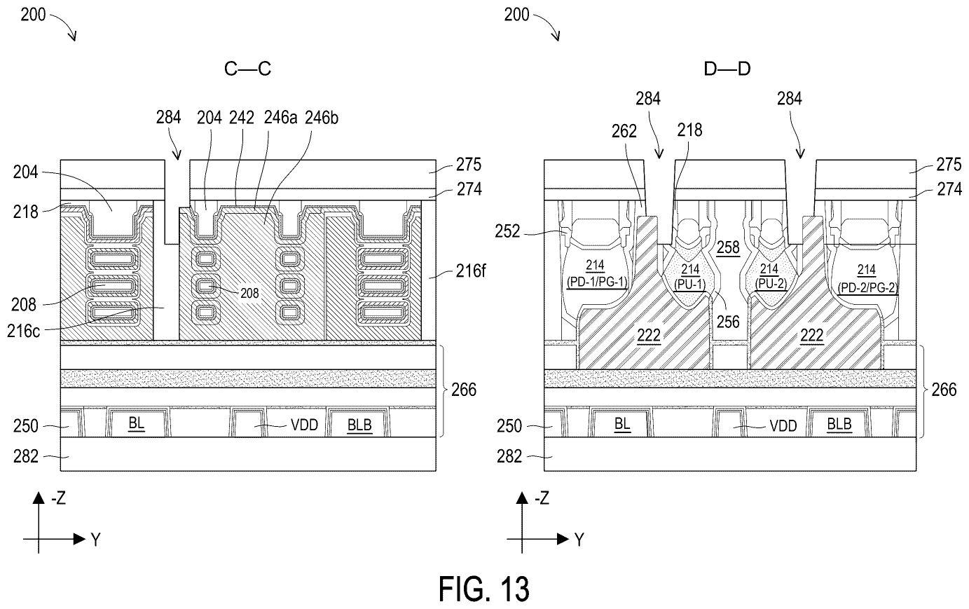

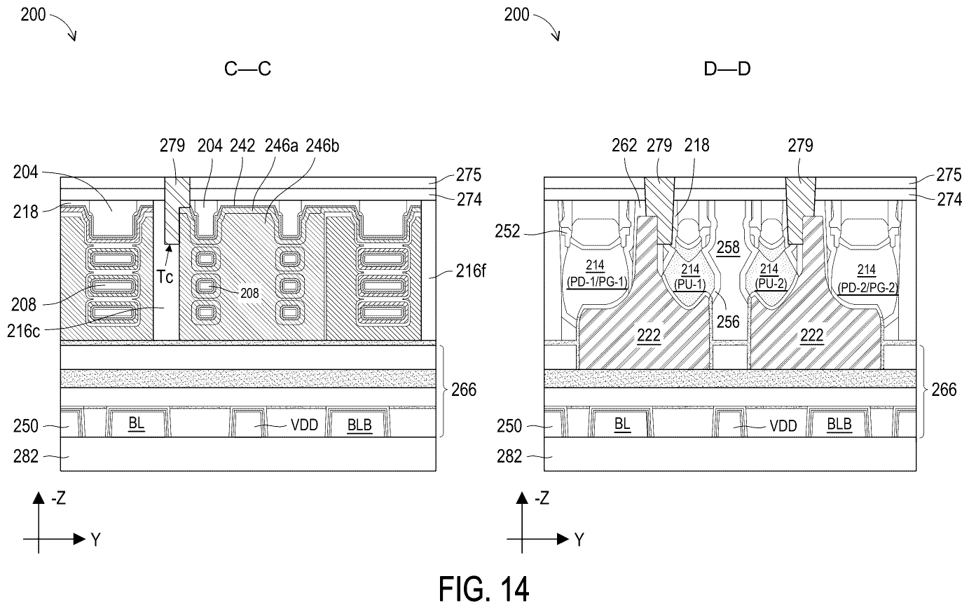

In FIGS. 11 and 12, the top surface Tc of the backside butted contact 279 is below the top surface of the semiconductor base 204 and below the bottommost one of the channel layers 208. As shown in FIGS. 13 and 14, the depth of the trenches 284 may extend beyond the top surface of the semiconductor base 204 at the block 304, such that the top surface Tc of the backside butted contact 279 is above the top surface of the semiconductor base 204. The trenches 284 exposes more sidewall surface of the source/drain contacts 222, as shown in FIG. 13. As a result, the contact area between the backside butted contact 279 and the source/drain contacts 222 is further increased, as shown in FIG. 14. The larger contact area further reduces contact resistance. Depending on the depth of the trenches 284, the top surface Tc of the backside butted contact 279 may be above the bottom surface of the bottommost one of the channel layers 208.

Although not intended to be limiting, one or more embodiments of the present disclosure provide many benefits to a semiconductor device and the formation thereof. For example, the present disclosure reduces frontside conductive feature density and provides more freedom to the FMLI design by having a backside butted contact. Thus, the frontside metal lines may have an increased width and a reduced resistance, which may reduce voltage drop and wasted energy during operations of the semiconductor device. The backside butted contact is spaced apart from adjacent source/drain features, thus source/drain feature loss is avoided during the formation of the backside butted contact, and performance of the semiconductor device may be improved. Further, embodiments of the present disclosure can be readily integrated into existing semiconductor manufacturing processes. For example, the backside butted contact may be formed together with other backside vias (e.g., backside vias below source/drain features for power lines) of the semiconductor device.

In one exemplary aspect, the present disclosure is directed to a semiconductor structure. The semiconductor structure includes an epitaxial feature disposed in an active region, a frontside contact disposed directly above and in electrical coupling with the epitaxial feature, a metal gate stack, an inner spacer interposing the metal gate stack and the epitaxial feature, and a backside contact in physical contact with a bottom portion of the metal gate stack and in physical contact with a bottom portion of the frontside contact. In some embodiments, in a top view of the semiconductor structure, the backside contact and the active region is free of overlapping area. In some embodiments, the semiconductor structure further includes a dielectric structure separating the backside contact from physically contacting the epitaxial feature. In some embodiments, a sidewall of the backside contact directly interfacing a sidewall of the epitaxial feature. In some embodiments, the semiconductor structure further includes a gate-cut dielectric feature abutting the metal gate stack. In a top view of the semiconductor structure, the gate-cut dielectric feature overlaps with the frontside contact. In some embodiments, in the top view the backside contact overlaps with the gate-cut dielectric feature. In some embodiments, the metal gate stack includes a gate dielectric layer and a gate electrode layer, and the backside contact physically contacts the gate electrode layer. In some embodiments, the metal gate stack intersects an end portion of the active region. In some embodiments, the active region is a first active region and the epitaxial feature is a first epitaxial feature, the semiconductor structure further includes a second epitaxial feature disposed in a second active region. The frontside contact is disposed directly above and in electrical coupling with the first and second epitaxial features. In some embodiments, the first epitaxial feature is a p-type epitaxial feature, and the second epitaxial feature is an n-type epitaxial feature.

In another exemplary aspect, the present disclosure is directed to a semiconductor structure. The semiconductor structure includes an active region including a semiconductor base, a stack of nanostructures over the semiconductor base, and an epitaxial feature over the semiconductor base and abutting the nanostructures, the active region extending lengthwise in a first direction, an isolation feature disposed on sidewalls of the semiconductor base, a metal gate stack wrapping around each of the nanostructures, the metal gate stack extending lengthwise in a second direction perpendicular to the first direction, a first contact feature disposed directly above and in electrical coupling with the epitaxial feature, and a second contact feature disposed directly under and in electrical coupling with both the first contact feature and the metal gate stack. The isolation feature separates the second contact feature from physically contacting the semiconductor base. In some embodiments, the first contact feature extends lengthwise in the second direction, and the second contact feature extends lengthwise in the first direction. In some embodiments, in a cross-sectional view of the semiconductor structure cut along the first direction, the second contact feature partially covers a bottom surface of the metal gate stack. In some embodiments, in a cross-sectional view of the semiconductor structure cut along the first direction, the second contact feature fully covers a bottom surface of the metal gate stack. In some embodiments, in a top view of the semiconductor structure, the second contact feature is spaced apart from the active region. In some embodiments, a top surface of the second contact feature is below a top surface of the semiconductor base. In some embodiments, a top surface of the second contact feature is above a top surface of the semiconductor base.

In yet another exemplary aspect, the present disclosure is directed to a static random-access memory (SRAM) cell. The SRAM cell includes a first active region and a second active region extending lengthwise along a first direction, a first metal gate stack intersecting the first active region in forming a first pull-up transistor of the SRAM cell, a second metal gate stack intersecting the second active region in forming a second pull-up transistor of the SRAM cell, a first contact feature disposed between the first and second metal gate stacks and extending lengthwise along a second direction perpendicular to the first direction, the first contact feature disposed above and in electrical connection with a source/drain feature of the first pull-up transistor, and a second contact feature in physical contact with a bottom surface of the first contact feature and a bottom surface of the second metal gate stack. In a top view of the SRAM cell, the second contact feature is spaced apart from a bottom surface of the source/drain feature of the first pull-up transistor. In some embodiments, the second metal gate stack intersects an end portion of the first active region. In some embodiments, the second metal gate stack includes a gate dielectric layer and a gate electrode layer, and the gate electrode layer is exposed in the bottom surface of the second metal gate stack and in physical contact with the second contact feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor structure, comprising:
an active region extending lengthwise in a first direction;
a metal gate stack engaging a channel region of the active region in forming a transistor, the metal gate stack extending lengthwise in a second direction different from the first direction, the metal gate stack comprising a gate dielectric layer and a gate electrode over the gate dielectric layer, the gate electrode comprising a titanium-containing material;
a gate spacer extending along a sidewall of the metal gate stack, a dielectric constant of the metal gate stack being greater than a dielectric constant of the gate spacer;
an epitaxial feature disposed in a source/drain region of the active region;
a frontside contact disposed above and in electrical coupling with the epitaxial feature; and
a backside contact interfacing with a bottom portion of the metal gate stack and interfacing with a bottom portion of the frontside contact.

2. The semiconductor structure of claim 1, wherein the frontside contact extends lengthwise along the second direction, and the backside contact extends lengthwise along the first direction.

3. The semiconductor structure of claim 1, wherein the channel region comprising a plurality of nanostructures vertically stacked, and the metal gate stack wraps around at least one of the nanostructures.

4. The semiconductor structure of claim 1, wherein the backside contact includes first and second sidewalls opposing to each other and spaced apart along the second direction, the first sidewall is facing the active region and the second sidewall is facing away from the active region, wherein when viewed from top the first sidewall is offset from the active region along the second direction.

5. The semiconductor structure of claim 4, wherein the backside contact is spaced apart from the epitaxial feature.

6. The semiconductor structure of claim 1, wherein the backside contact includes first and second sidewalls opposing to each other and spaced apart along the second direction, the first sidewall is facing the active region and the second sidewall is facing away from the active region, wherein when viewed from top the first sidewall aligns with an edge of the active region while the backside contact and the active region are free of overlapping area.

7. The semiconductor structure of claim 6, wherein the backside contact interfaces with the epitaxial feature.

8. The semiconductor structure of claim 1, wherein the gate electrode comprises a work function layer and a metal fill layer over the work function layer, and the backside contact interfaces with the work function layer.

9. The semiconductor structure of claim 1, wherein the gate electrode comprises a work function layer and a metal fill layer over the work function layer, and the backside contact interfaces with the metal fill layer.

10. The semiconductor structure of claim 1, wherein the transistor is a pull-up transistor of a memory cell.

11. A semiconductor structure, comprising:
first and second active regions extending lengthwise along a first direction;
first and second gate structures extending lengthwise along a second direction different from the first direction, the first gate structure engaging the first active region in forming a first transistor, the second gate structure engaging the second active region in forming a second transistor;
a frontside contact disposed over a source/drain region of the first transistor and in electrical coupling with the source/drain region of the first transistor; and
a backside contact interfacing with a bottom surface of the second gate structure and a bottom surface of the frontside contact,
wherein when viewed from top the backside contact and the first active region are free of overlapping area.

12. The semiconductor structure of claim 11, wherein the first transistor is a first pull-up transistor of a memory cell, and the second transistor is a second pull-up transistor of the memory cell.

13. The semiconductor structure of claim 11, further comprising:
a dielectric gate-cut feature abutting an end of the second gate structure, wherein the backside contact interfaces with the dielectric gate-cut feature.

14. The semiconductor structure of claim 11, wherein when viewed from top the backside contact is offset from the first active region along the second direction.

15. The semiconductor structure of claim 11, wherein when viewed from top the second gate structure overlaps with an end of the first active region.

16. The semiconductor structure of claim 11, further comprising:
third and fourth active regions extending lengthwise along the first direction, wherein the first gate structure engages the third active region in forming a third transistor, the second gate structure engages the fourth active region in forming a fourth transistor, wherein the frontside contact is in electric coupling with a source/drain region of the third transistor, and wherein along the second direction the backside contact is disposed between the first and third active regions.

17. A semiconductor structure, comprising:
an active region including a fin-shaped base, a stack of nanostructures over the fin-shaped base, and an epitaxial feature over the fin-shaped base and abutting the nanostructures, the active region extending lengthwise in a first direction;
an isolation feature disposed on sidewalls of the fin-shaped base, a top surface of the isolation feature being non-planar and below a top surface of the fin-shaped base;
a metal gate stack wrapping around at least one of the nanostructures, the metal gate stack extending lengthwise in a second direction perpendicular to the first direction;
a first contact feature disposed above and in electrical coupling with the epitaxial feature; and
a second contact feature disposed under and in electrical coupling with both the first contact feature and the metal gate stack,
wherein the isolation feature separates the second contact feature from interfacing with the fin-shaped base.

18. The semiconductor structure of claim 17, wherein the first contact feature extends lengthwise in the second direction, and the second contact feature extends lengthwise in the first direction.

19. The semiconductor structure of claim 17, wherein a top surface of the second contact feature is below the top surface of the fin-shaped base.

20. The semiconductor structure of claim 17, wherein a top surface of the second contact feature is above the top surface of the fin-shaped base.
